(19) United States
(12) Patent Application Publication
(10) Pub. No.: US 2016/0301395 A1
(43) Pub. Date: Oct. 13, 2016

(54) FLIP-FLOP CIRCUIT, AND SEMICONDUCTOR INTEGRATED CIRCUIT DEVICE

(71) Applicant: Socionext Inc., Yokohama-shi (JP)

(72) Inventors: Hiroshi Suzuki, Hachioji (JP); Toshiharu Nozawa, Moka (JP)

(73) Assignee: Socionext Inc., Yokohama-shi (JP)

(21) Appl. No.: 15/078,294

(22) Filed: Mar. 23, 2016

(30) Foreign Application Priority Data
Apr. 8, 2015 (JP) 2015-079197

(51) Int. Cl. H03K 3/3562; H03K 3/037

(52) U.S. Cl. CPC H03K 3/35625; H03K 3/0372

(57) ABSTRACT

A flip-flop circuit includes a first gate, a first latch, a second gate, a second latch and a third gate. The first gate is configured to operate in accordance with a first edge of a clock signal, and the first latch is configured to hold an output data of the first gate. The second gate is configured to operate in accordance with a second edge of the clock signal, and the second latch is configured to hold an output data via the second gate. The third gate, which is provided between the first latch and the second latch in series with the second gate, is configured to operate in accordance with a control signal which is a delayed signal of the clock signal.

### CROSS-REFERENCE TO RELATED APPLICATION

This application is based upon and claims the benefit of priority of the prior Japanese Patent Application No. 2015-079197, filed on Apr. 8, 2015, the entire contents of which are incorporated herein by reference.

### FIELD

The embodiments discussed herein are related to a flip-flop circuit, and a semiconductor integrated circuit device.

### BACKGROUND

In the past, a scan test for a random logic circuit has been known as an example of designing manners for easily performing tests of a semiconductor integrated circuit device (LSI). The scan test is realized, for example, that a flip-flop (FF: Flip-Flop) of the circuit is replaced to a scan FF, and an input of the scan FF of the circuit is switched to constitute a shift register by a series connection in a scan test mode.

By a plurality of the above shift registers, a scan chain circuit, which controls and observes the scan FF from an external I/O (Input/Output) terminal of the LSI, has been constituted. Note that, in a normal operation mode, the input of the scan FF is switched so as to use a general FF.

As described above, in the scan test mode, the scan chain circuit is constituted by a plurality of scan FFs of the circuit by changing inputs thereof, however, a hold margin of the scan chain circuit is not secured, and a data penetration may be caused.

Further, so as to avoid the data penetration, a delay element such as a buffer circuit may be placed on a data path used for the scan test. However, in this case, a consumption power and an occupied area may be increased by the newly provided buffer circuit, etc. In addition, so as to avoid the data penetration, it may be possible to delay data or a control signal, however, a performance of the circuit under the normal operation mode may be degraded.

By the way, in the past, various scan flip-flops (flip-flop circuits) have been proposed.

Patent Document 1: Japanese Laid-open Patent Publication No. H05(1993)-315900

Patent Document 2: Japanese Laid-open Patent Publication No. 2010-133541

Patent Document 3: Japanese Laid-open Patent Publication No. H11(1999)-154848

Patent Document 4: Japanese Laid-open Patent Publication No. 2004-037183

### SUMMARY

According to an aspect of the embodiments, there is provided a flip-flop circuit includes a first gate, a first latch, a second gate, a second latch and a third gate. The first gate is configured to operate in accordance with a first edge of a clock signal, and the first latch is configured to hold an output data of the first gate.

The second gate is configured to operate in accordance with a second edge of the clock signal, and the second latch is configured to hold an output data via the second gate. The third gate, which is provided between the first latch and the second latch in series with the second gate, is configured to operate in accordance with a control signal which is a delayed signal of the clock signal.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a block diagram for illustrating an example of a flip-flop circuit;

FIG. 2 is a diagram for explaining operations of the flip-flop circuit depicted in FIG. 1;

FIG. 3 is a diagram for illustration a circuit applying the flip-flop circuit depicted in FIG. 1;

FIG. 4 is a timing diagram for explaining problems in the circuit depicted in FIG. 3;

FIG. 5 is a block diagram for illustrating a first embodiment of a flip-flop circuit;

FIG. 6 is a diagram for illustrating an example of a circuit generating a control signal of a third gate of the flip-flop circuit depicted in FIG. 5;

FIG. 7A and FIG. 7B are timing diagrams for explaining operations of the flip-flop circuit depicted in FIG. 5;

FIG. 8 is a block diagram for illustrating a modification of the flip-flop circuit, depicted in FIG. 5;

FIG. 9 is a block diagram for illustrating a second embodiment of a flip-flop circuit;

FIG. 10A and FIG. 10B are diagrams for illustrating an example of a third gate of the flip-flop circuit depicted in FIG. 9;

FIG. 11 is a block diagram for illustrating a first embodiment of a semiconductor integrated circuit device;

FIG. 12A and FIG. 12B are diagrams for illustrating a second embodiment of a semiconductor integrated circuit device; and

FIG. 13A and FIG. 13B are diagrams for illustrating a third embodiment of a semiconductor integrated circuit device.

### DESCRIPTION OF EMBODIMENTS

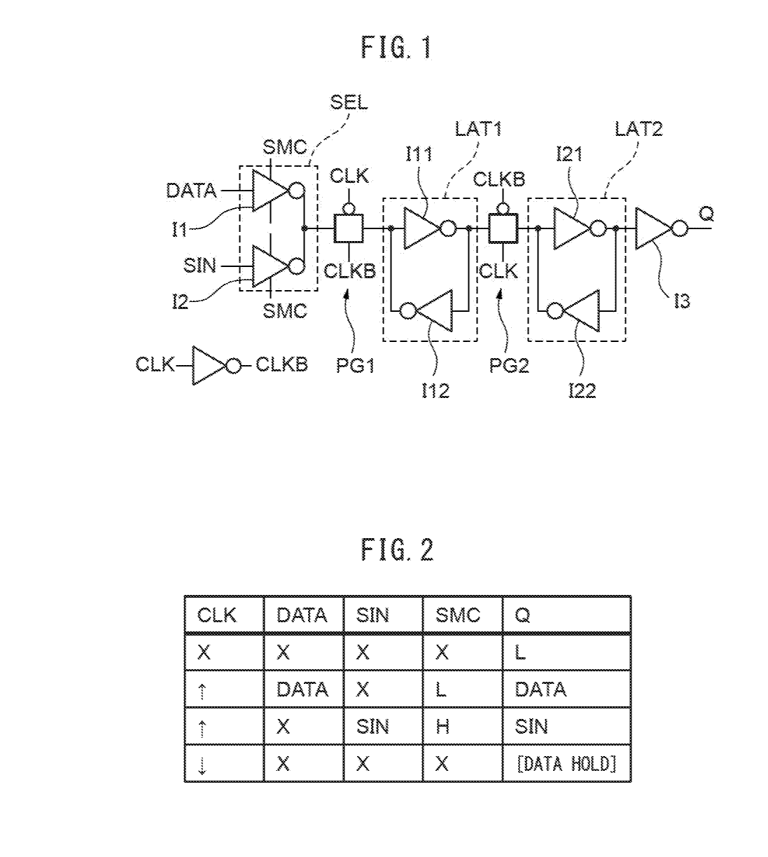

First, before describing embodiments of a flip-flop circuit and a semiconductor integrated circuit device, an example of a flip-flop circuit and problems thereof will be described first with reference to FIG. 1 to FIG. 4. FIG. 1 is a block diagram for illustrating an example of a flip-flop circuit, or illustrating an example of a master-slave type flip-flop circuit.

As depicted in FIG. 1, the flip-flop circuit includes a selector (multiplexer) SEL, a first and second gates (pass gate circuits) PG1 and PG2, a first and second latches (latch circuits) LAT1 and LAT2, and an inverter I3.

The selector SEL includes inverters I1 and I2 which are controlled by a scan mode signal SMC, and selects and outputs an actual data DATA used in a normal operation mode and a scan data SIN used in a scan test mode.

For example, in the normal operation mode, the scan mode signal SMC is set to a low level “L” so that the DATA is selected, and in the scan test mode, the scan mode signal SMC is set to a high level “H” so that the SIN is selected.

Specifically, in the normal operation mode, the inverter I1 is activated (inverter I2 is off), and the DATA is inverted by the inverter I1 and output to the pass gate circuit PG1. On the other hand, in the scan test mode, the inverter I2 is activated (inverter I1 is off), and the SIN is inverted by the inverter I2 and output to the pass gate circuit PG1.

The pass gate circuit (first gate) PG1 includes a p-channel type Metal-Oxide-Semiconductor transistor (pMOS transistor) of which gate terminal receives a clock signal CLK, and an n-channel type MOS transistor (nMOS transistor) of which gate terminal receives an inverted clock signal CLKB. Note that the signal CLKB indicates an inverted signal of the clock signal CLK.

An output signal (output data) of the pass gate circuit PG1 is input to the latch circuit (first latch) LAT1 and is held in the latch circuit LAT1, and an output signal (output data) of the latch circuit LAT1 is input to the latch circuit (second latch) LAT2 and is held in the latch circuit LAT2.

Note that, the latch circuit LAT1 is constituted by two inverters I11 and I12 of which inputs and outputs are cross-connected, and the latch circuit LAT2 is constituted by two inverters I21 and I22 of which inputs and outputs are cross-connected.

Further, similar to the pass gate circuit PG1, the pass gate circuit PG2 includes a pMOS transistor and an nMOS transistor, wherein the CLKB is input to a gate terminal of the pMOS transistor and the CLKB is input to a gate terminal of the nMOS transistor.

Specifically, the pass gate circuits PG1 and PG2 are alternatively switched on/off by the clock signal CLK (CLKB), and data stored in the latch circuit LAT1 of a master side and data stored in the latch circuit LAT2 of a slave side are controlled in accordance with the clock signal CLK. Note that an output signal of the latch circuit LAT2 is inverted by the inverter I3 and output as a Q output.

FIG. 2 is a diagram for explaining operations of the flip-flop circuit depicted in FIG. 1. In FIG. 2, a reference “↑” of the clock signal CLK denotes a rising edge of CLK, a reference “↓” of the clock signal CLK denotes a falling edge of CLK, and a reference “X” of each signal or data denotes a don't care state.

As depicted in FIG. 2, the master-slave type flip-flop circuit of FIG. 1 selects the DATA by controlling the scan mode signal SMC at “L” in the normal operation mode, and selects the SIN by controlling the scan mode signal SMC at “H” in the scan test mode. When the clock signal CLK is changed to “↓” the data at that time is held and output as the Q output of the flip-flop circuit.

Further, in accordance with the pass gate circuits PG1 and PG2 which are alternatively controlled by the clock signal CLK (CLKB), the DATA is output as the Q output by every clock period of CLK in the normal operation mode, and the SIN is output as the Q output by every clock period of CLK in the scan test mode.

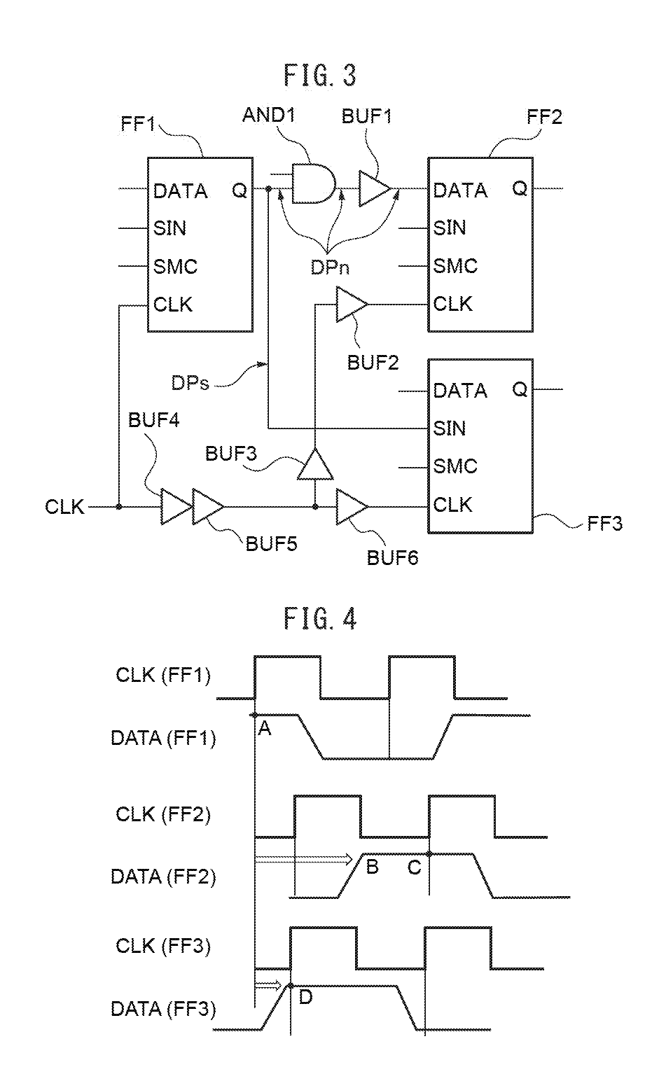

FIG. 3 is a diagram for illustration a circuit applying the flip-flop circuit depicted in FIG. 1, and illustration an example of a circuit (logic circuit) applying three master-slave type flip-flop circuits (FF1 to FF3) depicted in FIG. 1.

For example, the circuit depicted in FIG. 3 includes a logical conjunction circuit AND1 which actually operates as a logic circuit and a buffer circuit BUF1, and the AND1 performs a logical conjunction between the output signal Q of the FF1 supplied to one input of the AND1 and a signal supplied to the other input of the AND1. Further, an output signal of the AND1 is input to the FF2 via the BUF1 as the DATA.

Note that, a data path of the normal operation mode is a signal path DPn including a path from the output (Q) of the FF1 to a data input terminal (DATA) of the FF2 via the BUF1. Further, a data path of the scan test mode is a signal path DPs including a path from the output terminal (Q) of the FF1 directly to a scan input terminal (SIN) of the FF3.

Specifically, for example, in the normal operation mode, the output signal Q of a previous stage flip-flop FF1 is transferred to the data input terminal DATA of a subsequent stage flip-flop FF2 via a plurality of logic gates in general (in FIG. 3, AND1).

Note that, for example, in the scan test mode, a flip-flop chain is constituted by a plurality of flip-flops, wherein the output signal Q of the previous stage flip-flop FF1 is directly transferred to the scan input terminal SIN of a subsequent stage flip-flop FF3. Specifically, the scan test mode is performed to realize a functional test of a flip-flop, and therefore no logic gate is provided in the data path DPs of the scan test mode.

FIG. 4 is a timing diagram for explaining problems in the circuit depicted in FIG. 3, and explaining a data penetration caused in the flip-flop.

As depicted in FIG. 4, in the normal operation mode, data (DATA) fetched to the previous flip-flop FF1 at a rising timing (point A) of the clock signal CLK may cause a delay by the data path DPn. Therefore, in the subsequent flip-flop FF2, the fetched data is reflected as an input data at a point B, and transferred and correctly fetched by the subsequent flip-flop FF2 at a rising timing (point C) next to the point B.

On the other hand, in the scan test mode, a delay caused in the data path DPs of the scan test is small, and therefore, the DATA fetched to the previous flip-flop FF1 at the point A is immediately arrived at the scan input terminal SIN of the subsequent flip-flop FF3 at a point D.

Note that, during flip-flops, a timing of the clock signal CLK may be deviated, and as depicted in FIG. 4, a data penetration may be caused at point D, so that the DATA fetched to the previous flip-flop FF1 may be transferred and fetched in the subsequent flip-flop FF3 by the same timing of the clock signal CLK.

So as to avoid the data penetration, a delay element such as a buffer circuit may be inserted in the data path DPs of the scan test, however, in this case, a consumption power or a occupied area may be increased based on the newly provided buffer circuit. Further, so as to avoid the data penetration, it is considered to delay the data or control signals, however, in this case, an operation speed in the normal operation mode may be reduced.

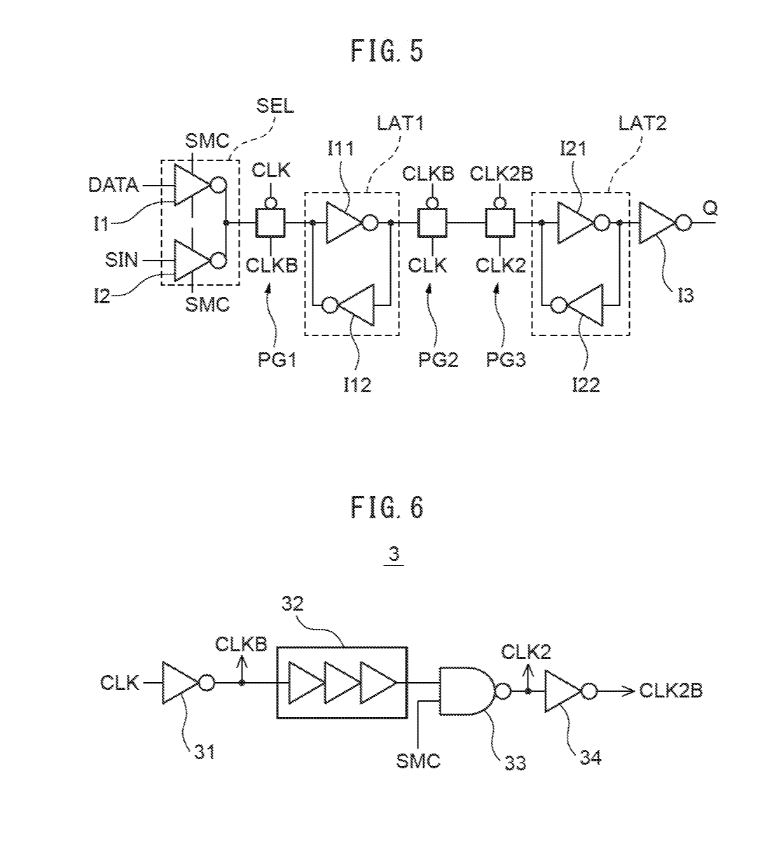

Below, embodiments of a flip-flop circuit and a semiconductor integrated circuit device will be explained with reference to the accompanying drawings. FIG. 5 is a block diagram for illustrating a first embodiment of a flip-flop circuit, and illustrating an example of a master-slave type flip-flop circuit.

As apparent from a comparison of FIG. 5 with previously described FIG. 1, in the flip-flop circuit of the first embodiment, a third gate (pass gate circuit) PG3 is provided between the second gate (pass gate circuit) PG2 and the second latch (latch circuit) LAT2.

As depicted in FIG. 5, the flip-flop circuit includes a selector (multiplexer) SEL, the first and second gates (selector (Multiplexer), first and second gates (pass gate circuits) PG1 and PG2, the first and second latches (latch circuits) LAT1 and LAT2, and the inverter I3.

The selector SEL includes the inverters I1 and I2 which are controlled by the scan mode signal SMC, and selects and outputs an actual data DATA used in a normal operation mode, and a scan data SIN used in a scan test mode in accordance with the scan mode signal SMC.

For example, in the normal operation mode, the actual data DATA is selected by controlling the scan mode signal SMC at a low level “L,” and in the scan test mode, the scan data SIN is selected by controlling the scan mode signal SMC at a high level “H”.

Specifically, in the normal operation mode, the inverter I1 is activated (inverter I2 is inactivated) and the actual data DATA is inverted and outputs to the pass gate circuit PG1, and in the scan test mode, the inverter I2 is activated (inverter I1 is inactivated) and the scan data SIN is inverted and outputs to the pass gate circuit PG1.

The pass gate circuit (first gate) PG1 includes a pMOS transistor to which gate a clock signal CLK is input, and an nMOS transistor to which gate an inverted clock signal CLKB is input. Note that the signal CLKB is an inverted signal of the signal CLK.

An output signal (output data) of the pass gate circuit PG1 is input to the latch circuit (first latch) LAT1 and is held therein. Further, an output signal (output data) of the latch circuit LAT1 is input to the latch circuit (second latch) LAT2 and is held therein via the pass gate circuit (second gate) PG2 and the pass gate circuit (third gate) PG3.

Note that, similar to the pass gate circuit PG1, the pass gate circuit PG2 includes a pMOS transistor and an nMOS transistor, the gate of the pMOS transistor receives the inverted clock signal CLKB, and the gate of the nMOS transistor receives the clock signal CLK. Specifically, the pass gate circuits PG1 and PG2 are alternatively switched on/off in accordance with the clock signal CLK (CLKB).

Further, similar to the pass gate circuits PG1 and PG2, the pass gate circuit PG3 includes a pMOS transistor and an nMOS transistor. In the pass gate circuit PG3, the gate of the pMOS transistor receives an inverted clock signal CLK2B, and the gate of the nMOS transistor receives a clock signal CLK2. Note that the clock signal CLK2 (CLK2B) is a delayed signal of the clock signal CLK (CLKB).

Specifically, the pass gate circuits PG1 and PG2 are alternatively switched on/off in accordance with the clock signal CLK (CLKB), the pass gate circuit PG3 is controlled to switch by a little late after switching the pass gate circuit PG2.

Therefore, a latch circuit LAT2 of a slave side may not fetch an output signal of the pass gate circuit PG2, or an output signal of a latch circuit LAT1 of a master side, until the pass gate circuit PG3 is switched on, so that a data penetration may be avoided. In this case, an output signal of the latch circuit LAT2 is inverted by an inverter I3 and output as a Q output of the flip-flop circuit.

Note that, in the normal operation mode, the pass gate circuit PG3 is held at a switched on state, and the latch circuit LAT2 of the slave side directly receives an output signal of the pass gate circuit PG2, and thus a performance degradation of the flip-flop circuit under the normal operation mode may be reduced.

In FIG. 5, the latch circuits LAT1 and LAT2 are constituted by two inverters I11, I12 and I21, I22 which are cross-connected, however, the latch circuits LAT1 and LAT2 may be applied various kind of latch circuits.

As described above, the pass gate circuits PG1 and PG2 are alternatively switched on/off in accordance with the clock signal CLK (CLKB), and in the scan test mode, the pass gate circuit PG3 is switched on/off by a little late after switching the pass gate circuit PG2 in accordance with the clock signal CLK2 (CLK2B). Note that, in the normal operation mode, the pass gate circuit PG3 is held at a switched on state.

Therefore, data held in the latch circuit LAT1 of the master side and the latch circuit LAT2 of the slave side are controlled in accordance with the clock signal CLK with decreasing a data penetration in the scan test mode and a performance degradation of the flip-flop circuit under the normal operation mode.

FIG. 6 is a diagram for illustrating an example of a circuit (control signal generation circuit 3) generating a control signal of a third gate of the flip-flop circuit depicted in FIG. 5. As depicted in FIG. 6, the control signal generation circuit (delay circuit) 3 includes inverters 31, 34, a delay unit 32, and a NAND circuit 33.

The inverter 31 receives and inverts a clock signal CLK, generates an inverted clock signal CLKB, and input the inverted clock signal CLKB to the delay unit 32. The delay unit 32 includes a plurality of buffers, delays the inverted clock signal CLKB, and input the delayed inverted clock signal to one input of the NAND circuit 33.

Further, the scan mode signal SMC is input to the other input of the NAND circuit 33, the NAND circuit 33 performs a NAND logic of the CLKB and the SMC, and generates a control signal CLK2 and also generates a control signal CLK2B by inverting the CLK2 by the inverter 34.

Note that the control signal generation circuit 3 may be provided at each of the flip-flop circuits, for example, respective specific nodes of a clock tree, e.g., commonly provided for a plurality of flip-flops. Further, the control signal generation circuit 3 depicted in FIG. 6 is only an example, and various modifications and changes of the control signal generation circuit 3 may be possible.

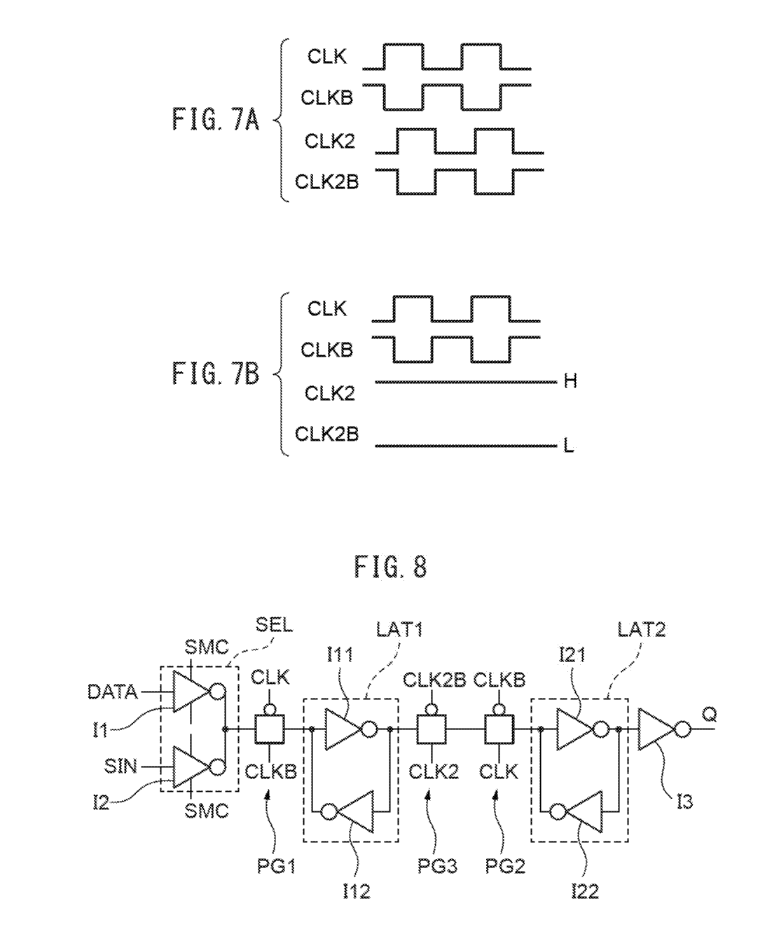

FIG. 7A and FIG. 7B are timing diagrams for explaining operations of the flip-flop circuit depicted in FIG. 5. Note that FIG. 7A illustrates clock waveforms (control signals) in the scan test mode (scan mode signal SMC is at a high level “H”), and FIG. 7B illustrates clock waveforms in the normal operation mode (scan mode signal SMC is at a low level “L”).

As depicted in FIG. 7A, in the scan test mode, waveforms of control signals CLK2, CLK2B of the pass gate circuit (third gate) PG3 of the flip-flop circuit-depicted in FIG. 5 correspond to waveforms of delaying clock signals CLK, CLKB.

The pass gate circuit PG3 performs on/off operations from those of the pass gate circuit PG2 controlled by the CLK, CLKB by delaying a specific delay value obtained by the delay unit 32.

Therefore, even when the pass gate circuit PG2 is already switched on, the latch circuit LAT2 of the slave side does not fetch the output signal of the latch circuit LAT1 of the master side until the pass gate circuit PG3 is switched on.

Further, after when the pass gate circuit PG3 is switched on, the latch circuit LAT2 starts to fetch the output signal of the latch circuit LAT1, so that a timing of changing the output signal of the latch circuit LAT1 is delayed. Therefore, a scan input SIN from a previous stage FF1 to a subsequent stage FF3 may be delayed, and it is possible to avoid a data penetration in the scan test mode.

On the other hand, a fetching operation of the output signal of the latch circuit LAT1 to the latch circuit LAT2 is completed by the timing when the pass gate circuit PG2 is switched off, even when the pass gate circuit PG3 is switched on. Therefore, it is possible to avoid a data penetration when the signal CLK2 falls in the flip-flop circuit.

Further, as depicted in FIG. 7B, in the normal operation mode, the control signals CLK2 and CLK2B of the pass gate circuit PG3 are controlled to “H” and “L,” so that the pass gate circuit PG3 is held at a switched on state.

Specifically, in the normal operation mode, the pass gate circuit PG3 is held at the switched on state, the latch circuit LAT2 of the slave side may fetch the output signal of the latch circuit LAT1 of the master side in accordance with on/off operations of the pass gate circuit PG2.

As described above, according to the first embodiment, a third gate PG3 is added to an internal of the flip-flop circuit, in the normal operation mode, the third gate PG3 is switched on, and the first and second gates PG1 and PG2 are controlled by the clock signals CLK and CLKB. Therefore, countermeasures in the scan test mode may be realized without reducing an operation speed in the normal operation mode.

Further, according to the first embodiment, the third gate PG3 is controlled by control signals CLK2 and CLKB which are delayed by a specific time from the clock signals CLK and CLKB, so that a margin for avoiding a data penetration in the scan test mode is obtained.

According to the first embodiment, a hold margin of a scan chain circuit in the scan test mode may be obtained with avoiding a reduction of an operation speed in the normal operation mode. Similar to this first embodiment, these effects may be obtained in other embodiments.

FIG. 8 is a block diagram for illustrating a modification of the flip-flop circuit depicted in FIG. 5. As apparent from a comparison of FIG. 8 with previously described FIG. 5, in the modification of the flip-flop circuit, the pass gate circuit (second gate) PG2 and the pass gate circuit (third gate) PG3 of the first embodiment are conversely arranged.

Specifically, as depicted in FIG. 3, in the modification of the flip-flop circuit, the output signal of the latch circuit LAT1 is input to the latch circuit (second latch) LAT2 via the pass gate circuit (third gate) PG3 and the pass gate circuit (second gate) PG2, and held on the second latch LAT2.

Note that the pass gate circuit PG2 is controlled by control signals CLK and CLKB, and the pass gate circuit PG3 is controlled by control signals CLK2 and CLK2B which are delayed signals of the control signals CLK and CLKB.

Therefore, even when the pass gate circuit PG2 is already switched on, the output signal of the latch circuit LAT1 of the master side is not transferred to the latch circuit LAT2 of the slave side until the pass gate circuit PG3 is switched on. Further, a fetching operation of the output signal of the latch circuit LAT1 to the latch circuit LAT2 is completed by the timing when the pass gate circuit PG2 is switched off, even when the pass gate circuit PG3 is switched on. Therefore, it is possible to obtain the similar effects as described in the flip-flop circuit of the first embodiment as depicted in FIG. 5.

Specifically, a scan input SIN from a previous stage FF1 to a subsequent stage FF3 may be delayed, and it is possible to avoid a data penetration in the scan test mode. Further, it is possible to avoid a data penetration when the signal CLK2 falls in the flip-flop circuit.

Note that, similar to the above described first embodiment, in the modification of the flip-flop circuit, the pass gate circuit PG3 is switched on in the normal operation mode, and the latch circuit LAT2 receives the output signal of the pass gate circuit PG2, and thus the operation speed in the normal operation mode is not reduced.

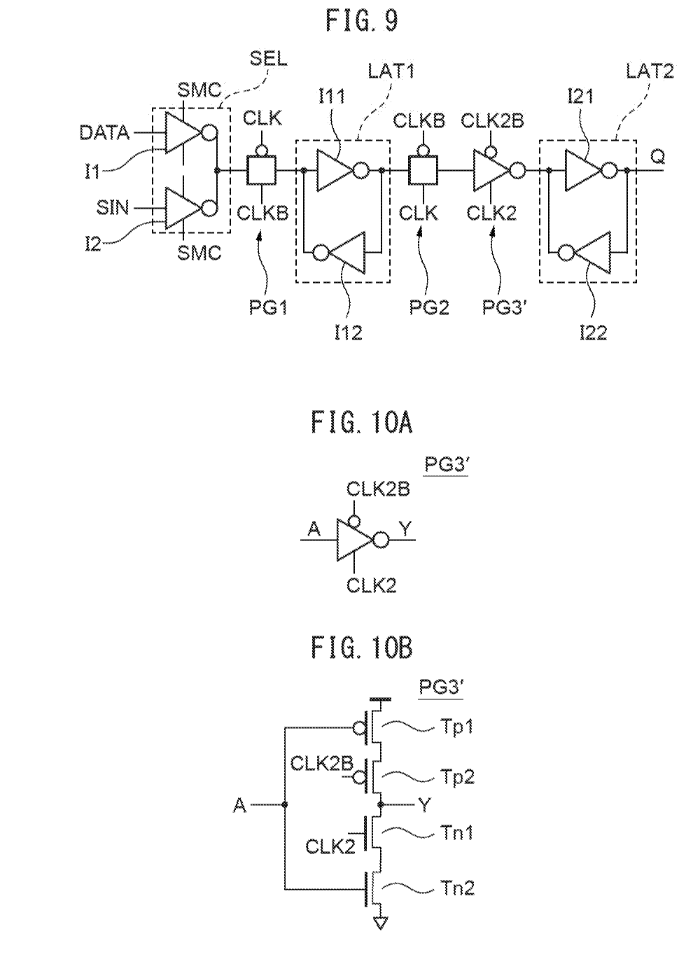

FIG. 9 is a block diagram for illustrating a second embodiment of a flip-flop circuit, and FIG. 10A and FIG. 10B are diagrams for illustrating an example of a third gate of the flip-flop circuit depicted in FIG. 9. Note that FIG. 10A illustrates an input-output relationship of a complex gate circuit (third gate) PG3′, and FIG. 10B is a circuit diagram illustrating an example of the complex gate circuit PG3′.

As apparent from a comparison of FIG. 9 with previously described FIG. 5, in the flip-flop circuit of the second embodiment, the pass gate circuit PG3 of the flip-flop circuit is changed to a complex gate circuit PG3′. Note that, in the flip-flop circuit of the second embodiment depicted in FIG. 10, the complex gate circuit PG3′ includes a function of an inverter, and thus, the inverter I3 depicted in FIG. 5 is omitted.

As depicted in FIG. 10, the complex gate circuit PG3′ includes pMOS transistors Tp1, Tp2, and nMOS transistors Tn1, Tn2, the transistors Tp1 and Tn2 constitute an inverter.

Specifically, the complex gate circuit PG3′ includes an inverter (Tp1, Tn2), and transistors Tp2 and Tn1. A gate of the transistor Tp2 receives a control signal CLK2B, and a gate of the transistor Tn1 receives a control signal CLK2.

Note that, the control signals CLK2 and CLK2B are delayed signals of the CLK and CLKB, and in the scan test mode, the complex gate circuit PG3′ operates (inversely operates) a little late after the on/off operation of the pass gate circuit PG2.

Further, similar to the above described first embodiment, in the second embodiment, in the normal operation mode, the control signals CLK2 and CLK2B of the complex gate circuit PG3′ are controlled to “H” and “L,” so that the complex gate circuit PG3′ is held at a switched on state and operates as a general inverter.

Therefore, according to the second embodiment, a hold margin of a scan chain circuit in the scan test mode may be obtained with avoiding a reduction of an operation speed in the normal operation mode. Note that, similar to the modification of the first embodiment, with reference to FIG. 8, the complex gate circuit PG3′ and the pass gate circuit PG2 may be conversely arranged.

Further, a fetching operation of the output-signal of the latch circuit LAT1 to the latch circuit LAT2 is completed by the timing when the pass gate circuit PG2 is switched off, even when the complex gate circuit PG3′ is switched on. Therefore, similar to the flip-flop circuit of the first embodiment, it is possible to avoid a data penetration when the signal CLK2 falls in the flip-flop circuit.

Furthermore, in the complex gate circuit PG3′ depicted in FIG. 10, it is possible to constitute an inverter by the transistors Tp2 and Tn1, input the control signal CLK2B to a gate of the transistor Tp1, and input the control signal CLK2 to a gate of the transistor Tn2.

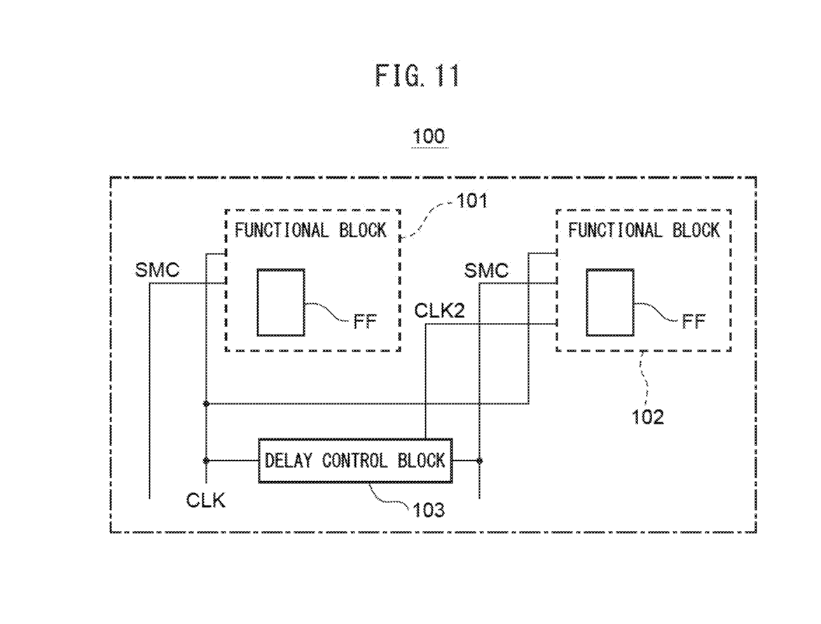

FIG. 11 is a block diagram for illustrating a first embodiment of a semiconductor integrated circuit device. As depicted in FIG. 11, the semiconductor integrated circuit device of the first embodiment, includes functional blocks 101 and 102, and a delay control block 103.

Each of the functional blocks 101 and 102 includes a flip-flop circuit FF, respectively. Note that the flip-flop circuit FF is, for example, a flip-flop circuit depicted in FIG. 5, FIG. 8 or FIG. 9, and does not include the control signal generation circuit (delay circuit) 3 for generating a control signal of the third gate as described with reference to FIG. 6.

As depicted in FIG. 11, in the semiconductor integrated circuit device of the first embodiment, the delay control block 103 corresponding to the control signal generation circuit 3 is not included in each of the flip-flop circuits, but is provided as a common circuit block.

Specifically, each of the functional blocks 101 and 102 (flip-flop circuits) receives a control signal CLK2 which is a delayed signal of the clock signal CLK from the delay control block 103.

Note that, in FIG. 11, two functional blocks 101 and 102 are only illustrated, and one flip-flop circuit FF is only illustrated in each of the functional blocks 101 and 102. However, these functional blocks and flip-flop circuits may be arranged as plural numbers.

Further, in FIG. 11, the control signal CLK2 is only illustrated from the delay control block 103 to each of the functional blocks 101 and 102. However, control signals from the delay control block 103 to each of the functional blocks 101 and 102 may include an inverted signal CLK2B of the signal CLK2, an inverted signal CLKB of the clock signal CLK, etc.

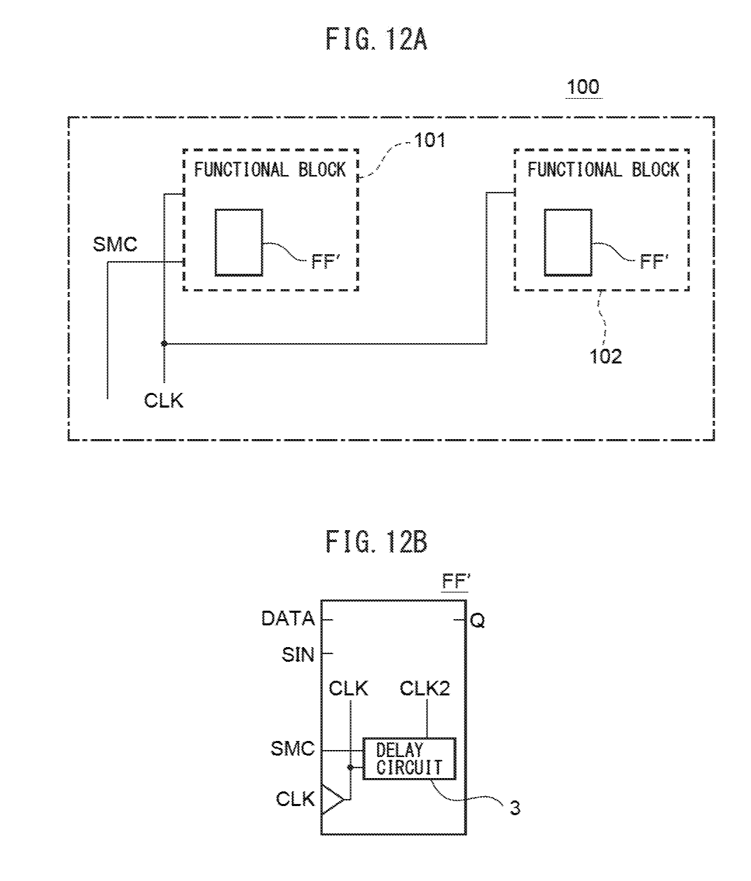

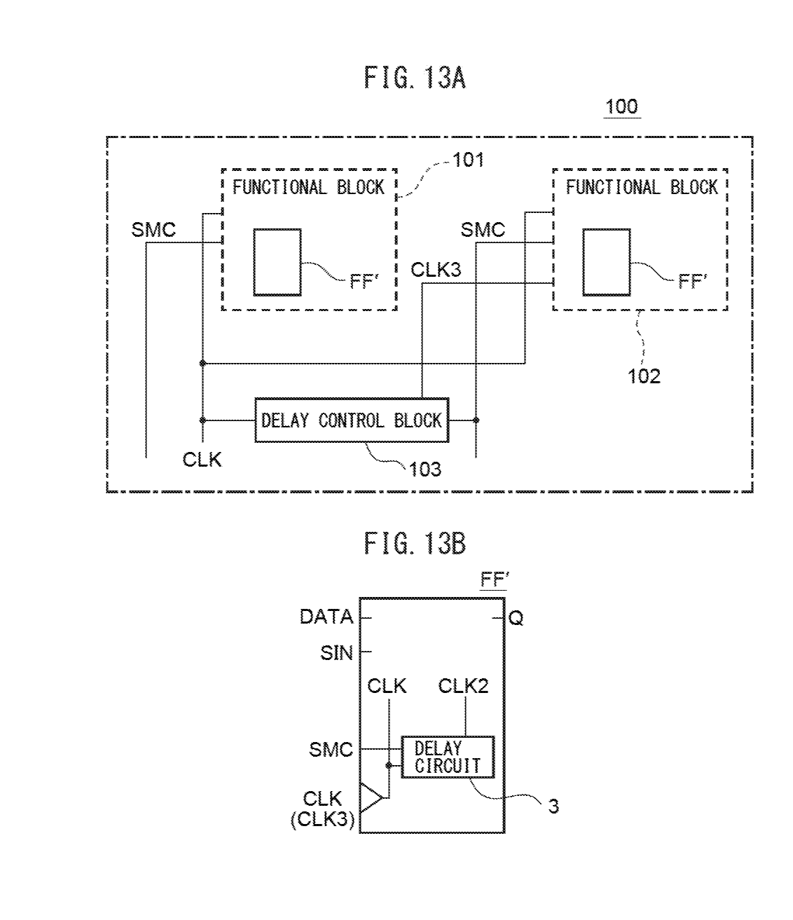

Further, the delay control block 103 is not limited to one, the delay control block 103 may be provided for a specific number of functional blocks, so that a plurality of delay control blocks 103 may be provided. These features may be similarly applied to FIG. 12 and FIG. 13.

As described above, according to the semiconductor integrated circuit device of the first embodiment, the control signals (CLK2, CLK2B) for the third gate may be supplied to the plurality of functional blocks 101, 102 (FF) by the delay control block 103, an area efficiency may be increased. Therefore, a circuit for generating a respective large delay value may be arranged in the delay control block 103, so that a large amount of adjustment may be possible between the functional blocks.

FIG. 12A and FIG. 12B are diagrams for illustrating a second embodiment of a semiconductor integrated circuit device. Note that FIG. 12A is a block diagram illustrating a semiconductor integrated circuit device, and FIG. 12B is a block diagram illustrating an example of a flip-flop FF′ of the semiconductor integrated circuit device depicted in FIG. 12A.

As apparent from a comparison of FIG. 12A with previously described FIG. 11, in the semiconductor integrated circuit device of the second embodiment, the delay control block 103 of the first embodiment is omitted. Instead that, as depicted in FIG. 12B, the control signal generation circuit (delay circuit) 3 which is previously explained with reference to FIG. 6 is provided in the flip-flop circuit FF7 in each of the functional blocks 101 and 102.

According to the semiconductor integrated circuit device of the second embodiment, it is possible to generate control signals CLK2, CLK2B including preferable delay values for the respective flip-flop circuits FF′ by using delay circuits (control signal generating circuits) 3 provided in each of the flip-flop circuits FF′. Specifically, the above described countermeasures may be applied to each path in the functional blocks 101 and 102 including the flip-flop circuits FF′.

FIG. 13A and FIG. 13B are diagrams for illustrating a third embodiment of a semiconductor integrated circuit device. Note that FIG. 13A illustrates a block diagram of a semiconductor integrated circuit device, and FIG. 13B illustrates an example of a flip-flop circuit FF′ of the semiconductor integrated circuit device depicted in FIG. 13A.

As apparent from a comparison of FIG. 13A with previously described FIG. 11 and FIG. 12A, similar to the first embodiment, in the semiconductor integrated circuit device of the third embodiment, the delay control block 103 is added to the second embodiment. Note that, similar to FIG. 12B, FIG. 13B illustrates a flip-flop circuit FF′ including a delay circuit 3.

In the semiconductor integrated circuit device of the third embodiment, the delay control block 103 receives a clock signal CLK (CLKB), generates a delayed clock signal CLK3 (CLK3B) which is a delayed signal of the clock signal CLK (CLKB), and commonly supplies the delayed clock signal CLK3 (CLK3B) to a plurality of functional blocks 101 and 102.

In the flip-flop circuit FF′ of each of the functional blocks 101 and 102, control signals CLK2, CLK2B are generated by the delay circuit (control signal generation circuit) 3, wherein the delay circuit 3 further delays the delayed clock signals CLK3, CLK3B which are output from the delay control block 103.

Alternatively, the delay circuit 3 delays the clock signals CLK, CLKB and generates control signals CLK2, CLK2B, or the delayed clock signals CLK3, CLK3B output from the delay control block 103 are used as the control signals CLK2, CLK2B.

As described above, according to the semiconductor integrated circuit device of the third embodiment, similar to the first embodiment, a circuit for generating a respective large delay value may be arranged in the delay control block 103, so that a large amount of adjustment may be possible between the functional blocks.

Further, according to the semiconductor integrated circuit device of the third embodiment, similar to the second embodiment, it is possible to generate control signals including preferable delay values for the respective flip-flop circuits FF′ by providing the delay circuit 3 in each of the flip-flop circuits FF′. Specifically, according to the semiconductor integrated circuit device of the third embodiment, a large amount of adjustment may be possible between the functional blocks, and further the countermeasures may be applied to each path in the functional blocks.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations can be made hereto without departing from the spirit and scope of the invention.

What is claimed is:

1. A flip-flop circuit comprising:
a first gate configured to operate in accordance with a first edge of a clock signal;
a first latch configured to hold an output data of the first gate;
a second gate configured to operate in accordance with a second edge of the clock signal;
a second latch configured to hold an output data via the second gate; and
a third gate, provided between the first latch and the second latch in series with the second gate, configured to operate in accordance with a control signal which is a delayed signal of the clock signal.

2. The flip-flop circuit as claimed in claim 1, wherein the third gate is provided between an output of the second gate and an input of the second latch.

3. The flip-flop circuit as claimed in claim 1, wherein the third gate is provided between an output of the first latch and an input of the second gate.

4. The flip-flop circuit as claimed in claim 1, wherein the third gate is a pass gate circuit including a p-channel type MOS transistor and an n-channel type MOS transistor.

5. The flip-flop circuit as claimed in claim 4, wherein
the flip-flop circuit is a scan test flip-flop circuit configured to switch and used in a scan test mode and in a normal operation mode; and
the pass gate circuit is controlled to a switched on state or a switched off state based on the control signal in the scan test mode, and is held at the switched on state in the normal operation mode.

6. The flip-flop circuit as claimed in claim 1, wherein the third gate is a composite gate circuit including an inverter, and a p-channel type MOS transistor and an n-channel type MOS transistor connected in series with the inverter.

7. The flip-flop circuit as claimed in claim 6, wherein
the flip-flop circuit is a scan test flip-flop circuit configured to switch and used in a scan test mode and in a normal operation mode; and
the p-channel type MOS transistor and the n-channel type MOS transistor connected in series with the inverter in the composite gate circuit are controlled to a switched on state or a switched off state based on the control signal in the scan test mode, and is held at the switched on state in the normal operation mode.

8. The flip-flop circuit as claimed in claim 1, wherein the flip-flop circuit further comprises a control signal generation circuit configured to receive the clock signal and generate the control signal.

9. The flip-flop circuit as claimed in claim 1, wherein
the first edge is one of a rising edge and a falling edge of the clock signal, and
the second edge is the other of the rising edge and the falling edge of the clock signal.

10. The flip-flop circuit as claimed in claim 1, wherein
the flip-flop circuit is a master-slave type flip-flop,
the first gate and the first latch constitute a master side of the master-slave type flip-flop, and
the second gate and the second latch constitute a slave side of the master-slave type flip-flop.

11. A semiconductor integrated circuit device comprising a plurality of functional block circuits each including at least one flip-flop circuit, wherein the flip-flop circuit comprises:
a first gate configured to operate in accordance with a first edge of a clock signal;
a first latch configured to hold an output data of the first gate;
a second gate configured to operate in accordance with a second edge of the clock signal;
a second latch configured to hold an output data via the second gate; and
a third gate, provided between the first latch and the second latch in series with the second gate, configured to operate in accordance with a control signal which is a delayed signal of the clock signal.

12. The semiconductor integrated circuit device as claimed in claim 11, wherein the semiconductor integrated circuit device further comprises a delay control block configured to receive the clock signal, generate a delayed signal of delaying the clock signal, and output the delayed signal to the functional block circuits.
